(19) United States
(12) Patent Application Publication
(10) Pub. No.: US 2012/0319223 A1
(43) Pub. Date: Dec. 20, 2012

(54) DIFFUSE OMNI-DIRECTIONAL BACK REFLECTORS AND METHODS OF MANUFACTURING THE SAME

(75) Inventors: Roger E. Welser, Providence, RI (US); Ashok K. Sood, Brookline, MA (US)

(73) Assignee: MAGNOLIA SOLAR, INC., Woburn, MA (US)

(21) Appl. No.: 13/528,581

(22) Filed: Jun. 20, 2012

Related U.S. Application Data
(63) Continuation-in-part of application No. 12/985,748, filed on Jan. 6, 2011.
(60) Provisional application No. 61/293,469, filed on Jan. 8, 2010.
(60) Provisional application No. 61/499,142, filed on Jun. 20, 2011.

(51) Int. Cl. H01L 31/0232; H01L 31/18; B82Y 20/00

(52) U.S. Cl. 257/432; 438/72; 257/E31.127; 257/E31.119; 977/773

(57) ABSTRACT

Ultra-high reflectivity is projected for internal reflectors comprised of a metal film and nanostructured transparent conductive oxide (TCO) bi-layer on the back side of a semiconductor device. Oblique-angle deposition can be used to fabricate indium tin oxide (ITO) and other TCO optical thin-film coatings with a porous, columnar nanostructure. The resulting low-n dielectric films can then be employed as part of a conductive omni-directional reflector (ODR) structure capable of achieving high internal reflectivity over a broad spectrum of wavelengths and a wide range of angles. In addition, the dimensions and geometry of the nanostructured, low-n TCO films can be adjusted to enable diffuse reflections via Mie scattering. Diffuse ODR structures enhance the performance of light trapping and light guiding structures in photonic devices.

### RELATED APPLICATIONS

This application claims the benefit of U.S. Provisional Application Ser. No. 61/499,142, filed Jun. 20, 2011, entitled DIFFUSE OMNI-DIRECTIONAL BACK REFLECTORS AND METHODS OF MANUFACTURING THE SAME, the entire disclosure of which is herein incorporated by reference, and this application is a continuation-in-part of co-pending U.S. patent application Ser. No. 12/985,748, filed Jan. 6, 2011, entitled QUANTUM WELL WAVEGUIDE SOLAR CELLS AND METHODS OF CONSTRUCTING THE SAME, the entire disclosure of which is herein incorporated by reference, which claims the benefit of U.S. Provisional Application Ser. No. 61/293,469, entitled EFFICIENT SOLAR CELL EMPLOYING MULTIPLE ENERGY-GAP LAYERS AND LIGHT-SCATTERING STRUCTURES AND METHODS FOR CONSTRUCTING THE SAME, filed Jan. 8, 2010, the entire disclosure of which is incorporated herein by reference.

### STATEMENT REGARDING FEDERALLY SPONSORED RESEARCH OR DEVELOPMENT

This invention was made with U.S. government support under Grant Number NNX11CE59P, awarded by the National Aeronautics and Space Administration (NASA) and Grant Number ERDA1-0000021389 awarded by the New York State Energy Research and Development Authority (NYSERDA). The government may have certain rights in this invention.

### FIELD OF THE INVENTION

This invention relates to semiconductor-based photovoltaic energy converters, also known as “solar cells”, and to the design and fabrication thereof. More particularly, this invention relates to back reflector structures for solar cells.

### BACKGROUND OF THE INVENTION

With appropriate electrical loading, photovoltaic solid state semiconductor devices, commonly known as solar cells, convert sunlight into electrical power by generating both a current and a voltage upon illumination. The current source in a solar cell is the charge carriers that are created by the absorption of photons. These photogenerated carriers are typically separated and collected by the use of PN or PIN junctions in semiconductor materials. The operational voltage of the device is limited by the dark current characteristics of the underlying PN or PIN junction. Thus improving the power output performance of any solid state solar cell generally entails simultaneously maximizing absorption and carrier collection while minimizing dark diode current.

Internal reflectors on the back side of a semiconductor structure can improve the performance of a variety of photovoltaic and optoelectronic devices, including light emitting diodes (LEDs), photodiode detectors, and solar cells. By incorporating a high performance back reflector, unabsorbed photons can be recycled and scattered back into the active regions of the device. Since unabsorbed and emitted photons strikes the back surface at a wide range of different angles, these back reflector structures are desirably omni-directional in nature. Simple metal films can function as ODR structures, but are limited to approximately 90-95% reflectivity in the best cases, and many common metals offer much lower internal reflectivity performance.

Two-layer structures consisting of a metal film and a low refractive index dielectric on a semiconductor increase the internal reflectivity over a broad spectrum of wavelengths and a wide range of angles. For useful background material, refer to J.-Q. Xi et al. in a 2005 Optics Letters article (“Omnidirectional Reflector Using Nanoporous SiO₂ as a Low-Refractive-Index Material,” Optics Letters, vol. 30, pp. 1518-1520, June 2005) where the theoretical performance of such a bi-layer reflector structure has been reviewed and compared theoretical and measured results for the specific case of a low-n SiO₂/silver (Ag) ODR structure on GaP. For further useful background material, refer to the Applied Physics Letters by Jong Kyu Kim et al. (K. K. Kim, T. Gessmann, E. F. Schubert, J.-Q. Xi, H. Luo, J. Cho, C. Sone, and Y. Park “GaInN Light-Emitting Diode with Conductive Omnidirectional Reflector Having a Low-Refractive-Index Indium-Tin Oxide Layer,” Applied Physics Letters, vol. 88, no. 012501, January 2006) which demonstrated a conductive ODR structure consisting of a low-n ITO/Ag bi-layer on a GaN-based LED.

As reviewed in the works of Xi et al., the reflectivity of a simple metal/dielectric ODR structure on a semiconductor is a function of the refractive index of the semiconductor (nₛₑₘᵢ), the refractive index of the dielectric (n_{die}), and the optical constants of the metal (nₘₑₜₐₗ and kₘₑₜₐₗ). For any given metal-semiconductor combination, the reflectivity can be maximized by lowering the refractive index of the dielectric. In the works of J.-Q. Xi et al. and Jong Kyu Kim et al., oblique angle deposition was employed to reduce the refractive index of the dielectric layer. Oblique-angle deposition is a method of growing a wide variety of porous thin films, and hence thin films with adjustable refractive index, enabled by surface diffusion and self-shadowing effects during the deposition process. Refer to D. J. Poxson, F. W. Mont, M. F. Schubert, J. K. Kim, and E. F. Schubert, “Quantification of Porosity and Deposition Rate of Nanoporous Films Grown by Oblique-Angle Deposition,” Appl. Phys. Lett. 93, 101914, September 2008, for more useful background material on oblique angle deposition. In oblique angle deposition, random growth fluctuations on the substrate produces a shadow region that incident vapor flux cannot reach, and a non-shadow region where incident flux deposits preferentially, thereby creating an oriented rodlike structure with high porosity. The deposition angle, defined as the angle between the normal to the sample surface and the incident vapor flux, results in the formation of nanorod structures that are tilted relative to the sample surface. Because the gaps between the nanorods can be much smaller than the wavelength of visible and infrared light, the nanostructured layers can be approximated as a single homogenous film with a refractive index intermediate between air and the nanorod material, decreasing in refractive index with increasing porosity.

It is desirable to provide a back reflector structure that improves efficiency of a photovoltaic device by increasing the internal reflectivity.

### SUMMARY OF THE INVENTION

Increased internal reflectivity is achieved by providing a metal film/nanostructured material bi-layer on the back side of a semiconductor device. The nanostructured material can comprise a transparent conductive oxide (TCO) layer. Oblique-angle deposition can be used to fabricate indium tin oxide (ITO) and other TCO optical thin-film coatings with a porous nanostructure. The resulting low-n dielectric films can then be employed as part of a conductive omni-directional (ODR) structure capable of achieving high internal reflectivity over a broad spectrum of wavelengths and a wide range of angles. In addition, the dimensions and geometry of the nanostructured, low-n TCO films can be adjusted to enable diffuse reflections via Mie scattering. Diffuse ODR structures enhance the performance of light trapping and light guiding structures in photonic devices, such as solar cells, LEDs and photodiodes.

The omni-directional reflector structure is comprised of a non-specular layer of dielectric material that is synthesized on the semiconductor device using oblique angle deposition. A metal film is deposited on the dielectric material to provide a multi-layer structure with increased internal reflectivity by incorporating a non-specular nanostructured material when coupled with the metal film. The non-specular layer can comprise an indium tin oxide (ITO) material or other appropriate material known in the art. The metal film can comprise aluminum, gold, silver, or other metal films readily apparent to those skilled in the art.

### BRIEF DESCRIPTION OF THE DRAWINGS

The invention description below refers to the accompanying drawings, of which:

FIG. 1 is a schematic cross-sectional side view of a thin film solar cell device according to an illustrative embodiment incorporating optical coatings to increase the optical path of incident light through the active region of the device;

FIG. 2A is a schematic diagram of the nanostructured materials synthesized on a substrate by performing an oblique angle deposition process, according to an illustrative embodiment;

FIG. 2B is a diagram of a scanning electronic microscope (SEM) image showing an array of nanostructured materials deposited by oblique angle evaporation on a substrate, according to various illustrative embodiments;

FIG. 3 is a graphical diagram showing porosity calculated from measured refractive index as a function of deposition angle and also showing a theoretical curve using a model parameter as a function of deposition angle, according to an illustrative embodiment;

FIG. 4 is a graphical diagram of experimentally derived variation in refractive index as a function of wavelength for dense and porous nanostructured materials, according to an illustrative embodiment;

FIG. 5A is a graphical diagram showing reflectivity as a function of wavelength for a specific example employing GaAs as a semiconductor and aluminum as a metal film, according to an illustrative embodiment;

FIG. 5B is a graphical diagram showing reflectivity as a function of wavelength for a another specific example employing GaAs as a semiconductor and gold as the metal film, according to an illustrative embodiment;

FIG. 5C is a graphical diagram showing reflectivity as a function of wavelength for a another specific example employing GaAs as a semiconductor and silver as the metal film, according to an illustrative embodiment;

FIG. 6 is a graphical diagram showing reflectivity as a function of wavelength for a plurality of nanostructured materials deposited on various substrates as compared to a metal-coated substrate and a bare uncoated substrate, according to various illustrative embodiments;

FIG. 7 is a schematic cross-sectional diagram of an omni-directional reflector (ODR) structure deposited on a semiconductor substrate, the ODR including a layer of non-specular material and a metal film, according to an illustrative embodiment; and

FIG. 8 is a graphical diagram showing scattering efficiency as a function of wavelength for spheres having diameters of 150 nm, 250 nm, 350 nm and 450 nm, according to exemplary illustrative embodiments; and

FIG. 9 is a flow chart of a procedure for fabricating an ODR structure, according to an illustrative embodiment.

### DETAILED DESCRIPTION

A typical thin film solar cell structure contains a limited volume of low band gap material, and thus requires advanced light trapping structures to reach its potential performance levels. Light management is achieved by assuring that incident photons are not lost due to reflections but are instead directed into the semiconductor absorbing layers. The scattering of incident light to ensure each photon has a non-normal trajectory is a strategy for increasing the optical path length of photons within the absorption layer. In addition, the application of a back reflector to bounce any unabsorbed photons back up into the active layers of the device is a beneficial aspect of any effective photovoltaic light trapping scheme. However, the most effective light trapping schemes will also direct light horizontally into the plane of the absorbing layer. Waveguide structures in which thin layers of high refractive index material are surrounded by low refractive index material provide a physical mechanism by which to achieve this type of in-plane light trapping.

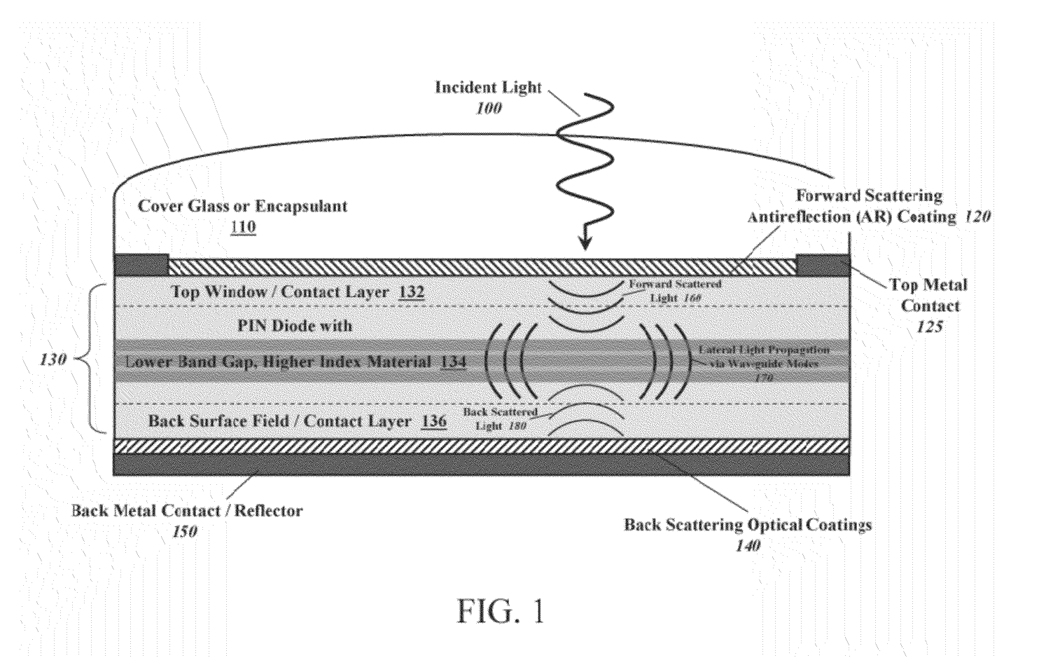

A schematic diagram of an exemplary waveguide solar cell structure is depicted in FIG. 1. This thin film waveguide solar cell incorporates lower band gap, higher index of refraction materials in the active region of the device, along with tailored, nanostructured optical coatings. The optical path length of light incident upon this novel device can be dramatically enhanced via coupling into laterally propagating waveguide modes. This combination of active device structure and passive coatings can redirect normally incident light into laterally propagating waveguides modes, and represents a dramatic change in thin film solar cell design.

With reference to FIG. 1, a thin film waveguide photovoltaic device is depicted according to an illustrative embodiment. In operation, incident light 100 first encounters a top covering surface 110, which can be a top cover glass, transparent epoxy or other light transmitting covering surface. The top covering surface 110 is located above a PIN diode semiconductor material device structure 130. The PIN diode structure is coated with a transparent optical coating 120 that minimizes reflection losses and scattering incident light into the underlying PIN diode 130. The refractive index of the top optical coating 120 is illustratively adapted to generate a graded index of refraction antireflection coating, consisting of one or more layers with refractive index intermediate between the covering surface material 110 and the PIN diode semiconductor material 130. In an illustrative embodiment one or more of the layers in the top optical coating 120 also incorporate nanoparticles or nanorods which differ in refractive index from that of their surrounding material. Nanostructured optical coatings 120 provide a mechanism by which incident light can be scattered horizontally into the plane of the underlying PIN diode 130.

In the illustrative embodiment shown in FIG. 1, the PIN diode device structure consists of top window/contact layers 132, back surface field/contact layers 136, and incorporates lower energy gap material 134 within the depletion region of the PIN diode structure 130. Lower energy gap material also tends to have a higher index of refraction, thereby resulting in the formation of a waveguide structure. The PIN diode device structure can consist of any common semiconductor materials, including but not limited to group IV materials (Si, Ge, SiGe, SiC, etc.), group III-V materials (GaAs, AlGaAs, InGaP, InGaAs, InP, AlInAs, GaAsSb, InAsSb, AlAsSb, GaN, InGaN, AlGaN, etc.), group II-VI materials (CdS, CdTe, etc.), and group I-III-VI₂ materials (CIGS, etc.). In another illustrative embodiment, the PIN diode device structure 130 comprises two or more PIN junctions. In yet another illustrative embodiment, the refractive index and thickness of the semiconductor materials used in the top window/contact layers 132 is tailored to function as part of a step graded refractive index antireflection structure. Electrical contact is made to the top window/contact layers 132 via metal contacts 125.

In the illustrative embodiment shown in FIG. 1, the back of the semiconductor PIN diode 130 is coated with a conductive, transparent optical coating 140. In an illustrative embodiment, the refractive index of the bottom optical coating 140 has a value of approximately 1.5 or lower, thereby creating an Omni-directional reflector when combined with the underlying metallic layer 150. In another illustrative embodiment, the bottom optical coating 140 consists of multiple layers differing in refractive index to form a distributed Bragg reflector. In yet another illustrative embodiment one or more of the layers in the bottom optical coating 140 also incorporate nanoparticles or nanorods. In yet another illustrative embodiment, the back-scattering structure, consisting of the back optical coating 140 and back metal contact 150, employ plasmonic structures. Plasmonic structures closely coupled to absorbing semiconductors can be used to increase the photocurrent in a variety of thin film solar cells. In general, the peak wavelength of the plasmon resonance is adjustable to match the absorption band of the nearby semiconductor layers, particularly the lower band gap, higher index material 134.

In the illustrative embodiment shown in FIG. 1, optical scattering by the nanoparticles or nanorods above the semiconductor device structure can lead to coupling of photons incident normal to the device surface into lateral optical propagation paths, i.e., paths parallel to the device surface. These parallel optical modes 170 result from the introduction of a lateral wave vector component into the forward scattered wave 160, and can dramatically enhance the optical path length of photons through thin film solar cell device structures. Unabsorbed, lower energy photons that are not coupled into the waveguide modes 170 pass through the PIN diode 130 device before striking a back scattering optical coating 140. Back-scattered light 180 is directed into the active, absorbing layers of the device by the presence of the back-scattering structure, which consists of the back optical coating 140 and back metal contact 150.

According to various embodiments, the front optical coating 120 is configured and arranged with transparent antireflection coating structures to reduce the reflection of incident photons at the material interface between the light transmitting covering surface 110 and semiconductor device structure 130. The back optical coating 140 is configured and arranged to maximize the reflection of unabsorbed photons back into the semiconductor device structure. In the various embodiments, the front coating 120 and the back coating 140 are implemented in accordance with industry standard processes and materials known to those skilled in the art. These materials include, but are not limited to, titanium dioxide, silicon dioxide, indium tin oxide, zinc oxide, and other transparent conductive oxides (TCOs). The antireflection coating can be synthesized using a variety of techniques, including sputtering, evaporation, and oblique-angle deposition. Transparent antireflection coating structures can comprise a single layer or multiple layers of materials having an index of refraction intermediate between the semiconductor structure 140 and the media in which the incident photons are delivered, which by way of example is illustrated as a cover glass or encapsulant 110 in FIG. 1. Back reflector structures can comprise either a single metallic layer, or a plurality of layers consisting of a metallic layer in combination with one or more layers of transparent optical material having an index of refraction lower than the semiconductor material. In an illustrative embodiment, Omni-directional reflectors (ODRs) combine a metal layer with a low-refractive index layer, provide ultra-high reflectivity over a wide range of wavelengths and incident angles.

When light is incident upon a semiconductor device coated with a continuous thin film material, the forward- and back-scattered light is well known to depend upon the optical properties of the thin film and surrounding environments which dictate the reflection, refraction, and absorption characteristics of the light. Employing an array of nanoparticles or nanorods can provide unique and desirable physical phenomena, particularly when the particle size is very small compared to the incident wavelength. In this case, the scattering and absorption characteristics of the forward wave front depend upon the size, shape, density, and permittivity of the nanoparticles. See for example, by way of useful background information, P. Matheu, S. H. Lim, D. Derkacs, C. McPheeters, and E. T. Yu, Metal and dielectric nanoparticle scattering for improved optical absorption in photovoltaic devices, Appl. Phys. Lett. 93, 113108-1-3 (2008). Nanoparticle coatings can provide additional light-trapping benefits when the adjoining semiconductor device structure contains distinct index of refraction steps. In this case, optical scattering by nanoparticles atop a semiconductor device structure can lead to coupling of photons incident normal to the device surface into lateral optical propagation paths, i.e., paths parallel to the device surface. These parallel optical modes result from the introduction of a lateral wave vector component into the scattered wave, and can dramatically enhance the optical path length of photons through thin film solar cell device structures.

Oblique-angle deposition is a method of growing arrays of nanorods in a wide variety of materials, enabled by surface diffusion and self-shadowing effects during the deposition process. Because the resulting thin films are porous, oblique-angle deposition is utilized as an effective technique for tailoring the refractive index of a variety of thin film materials (see for example, by way of useful background, J.-Q. Xi, M. F. Schubert, J. K. Kim, E. F. Schubert, M. Chen, S.-Y. Lin, W. Liu, and J. A. Smart, Optical Thin-Film Materials with Low Refractive Index for Broad-Band Elimination of Fresnel Reflection, Nat. Photon., vol. 1, pp. 176-179, 2007). In one illustrative embodiment, the bottom optical coating 140 comprises of a layer nanostructured, porous indium tin oxide layer with a refractive index of 1.5 or lower deposited by oblique angle deposition. In another illustrative embodiment, the top optical coating 120 comprises multiple layers, with at least one layer of dense indium tin oxide and at least one layer of porous indium tin oxide or porous titanium dioxide deposited by oblique-angle deposition.

In another illustrative embodiment, the top optical coating 120 and the bottom optical coating 140 comprise dielectric and/or metallic nanoparticles embedded within a dense optical film material. Examples include SiO₂ nanoparticles embedded within a dense layer of indium tin oxide, SiO₂ nanoparticles embedded within a dense layer of TiO₂, TiO₂ nanoparticles embedded within a transparent encapsulant, TiO₂ nanoparticles embedded within a dense layer of SiO₂, and metallic nanoparticles embedded within a dense layer of ITO. Note that deposition of the nanoparticles can occur according to conventional techniques in illustrative embodiments.

The operating voltage of a semiconductor PIN diode solar cell 130 is generally dictated by the underlying dark diode current of the device. The dark diode current of semiconductor devices is composed of several different components, all of which are dependent upon the energy gap of the material used in the active junction of the device. Typically, each cell in a solar cell consists of one type of material, and the energy gap of that material influences both the current and voltage output of the device. Lower energy gap material can enhance the current generating capability, but typically results in a lower operating voltage. Therefore, it is desirable to provide a device structure 130 that can harness the current generating capabilities of narrow energy gap material while also maintaining a high operating voltage.

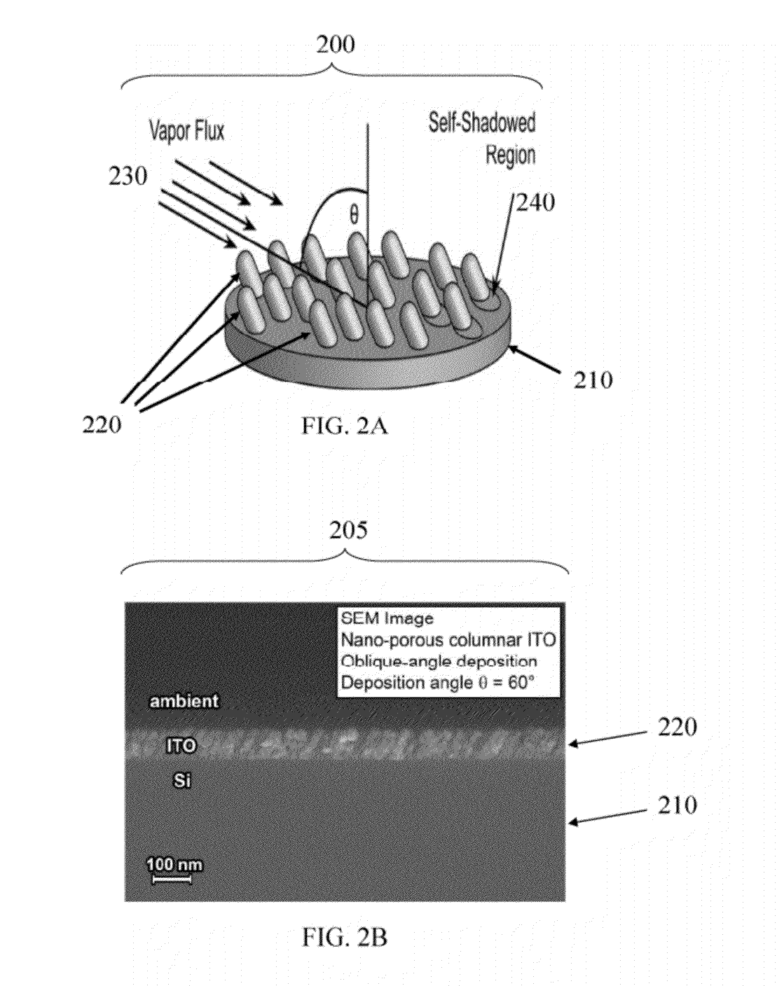

Reference is now made to FIGS. 2A and 2B showing exemplary illustrative embodiments of ODR back reflector structures for PV devices. FIG. 2A illustrates a schematic diagram of an illustrative embodiment of the nanostructured materials synthesized on a substrate according to an oblique angle deposition process. FIG. 2B is a cross-sectional diagram of a SEM micrograph image of a resulting nanostructured layer, such as indium tin oxide (ITO) deposited on a silicon substrate. As shown in the diagram 200 of FIG. 2A, a substrate 210, such as a Silicon substrate according to the illustrative embodiment, has a plurality of nanostructures 220, such as nanorods, deposited thereon, according to an oblique angle deposition process as described herein. Indium tin oxide (ITO) is a well-know transparent conductive oxide material that combines high optical transmittance with high electrical conductivity, and thus provides a desirable nanostructured material. The deposition angle of the nanostructure material (θ) is defined as the angle between the normal to the sample surface and the incident vapor flux 230. The deposition angle θ results in the formation of the nanorod structures 220 that are tilted relative to the sample surface. This results in a self-shadowed region 240 on the substrate 210 for each nanorod structure 220. ITO coatings are commonly employed in a variety of photonic devices, including LEDs and solar cells. While dense layers of ITO have a refractive index near 2.15, porous films have been demonstrated with a lower refractive index on the order of 1.5.

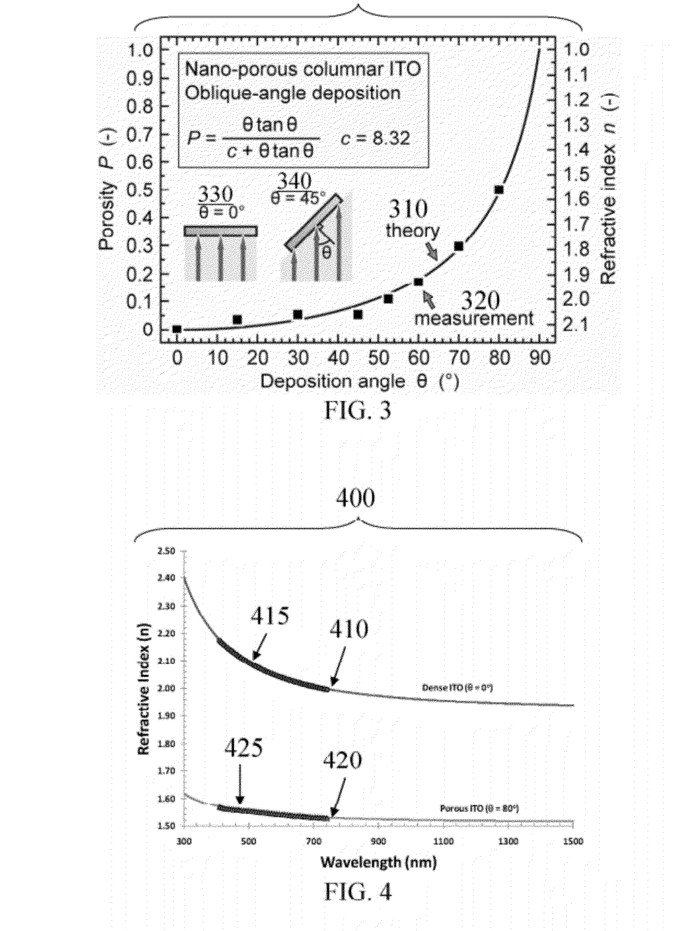

Reference is now made to FIG. 3 which summarizes the refractive index of ITO films at a wavelength of approximately 462 nm as a function of deposition angle, and highlights how the refractive index of ITO can be readily tuned when employing an oblique angle deposition process. As shown in the graphical diagram 300 of FIG. 3, the porosity calculated from the measured refractive index is plotted as a function of deposition angle. The theoretical curve 310, using a model parameter of c=8.32, is plotted, as well as the porosity calculated from the measured refractive index 320. The graphical diagram 300 of FIG. 3 shows the measurements fit excellently with the theory calculations. For a more detailed discussion of calculating the theoretical curve, refer to D. J. Poxson, F. W. Mont, M. F. Schubert, J. K. Kim, and E. F. Schubert, “Quantification of Porosity and Deposition Rate of Nanoporous Films Grown by Oblique-Angle Deposition,” Appl. Phys. Lett. 93, 101914, September 2008. Note that, for reference and assistance in understanding the graph, image 330 shows the deposition angle at 0° and image 340 shows the deposition angle at 45°.

FIG. 4 shows a graphical diagram that compares the refractive index of a dense ITO film having a deposition angle of approximately 0° as a function of wavelength to a porous, nanostructured ITO film synthesize at a deposition angle of approximately 80°. As shown, the refractive index of dense ITO (line 410) exhibits a significantly higher refractive index than the refractive index of the porous ITO (line 420). The experimentally derived variations in refractive index (415, 425) have each been plotted in the graphical diagram. To synthesize these oblique-angle deposited ITO films, an e-beam evaporation system is modified to include a sample mount fitted with a computer-controlled motor that can turn the sample to any deposition angle between approximately 0° and 90°. The ITO source material consists of a mixture of approximately 90% indium oxide and approximately 10% tin oxide by weight. During the deposition, the deposition rate was held steady at approximately 0.3 nm/s, as measured by a quartz crystal monitor inside the chamber, and the sample maintained at room temperature. After the deposition, all the samples are annealed, using a rapid thermal annealing (RTA) system, at approximately 550° C. for one minute while flowing O₂. Variable-angle spectroscopic ellipsometry was then used to determine the refractive index and the thickness of each ITO coating. The measured index of refraction (415, 425) is shown extrapolated over a range of wavelengths applicable to photovoltaic cells and used the Cauchy model to express the refractive index as a function of wavelength, thereby resulting in lines 410 and 420 for dense and porous ITO material, respectively.

The reflectivity of a wide variety of ODR structures incorporating ITO as the dielectric layer has been calculated using the equations summarized by Xi et al. and using the refractive index values for ITO shown in FIG. 4 for n_{die}.

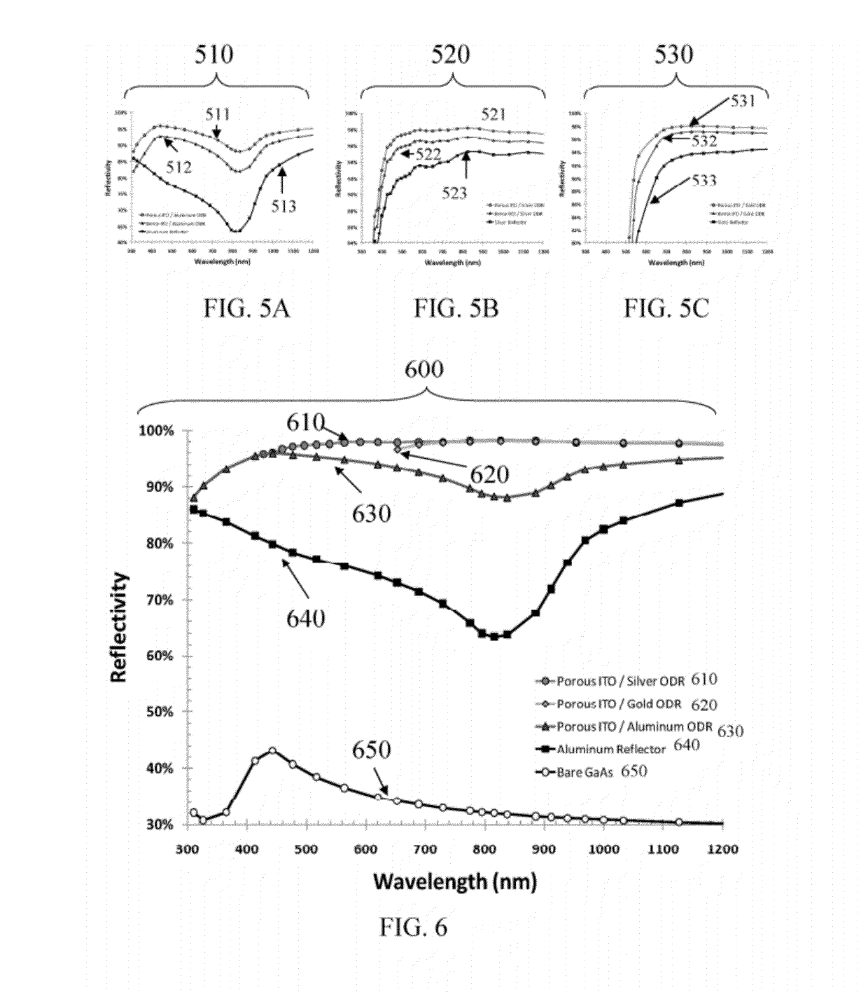

FIGS. 5A, 5B and 5C summarize some specific examples in which GaAs is the semiconductor and aluminum, gold, and silver, respectively are employed as the metal films. For a more detailed discussion of the optical constants for GaAs (nₛₑₘᵢ) and the metals (nₘₑₜₐₗ and kₘₑₜₐₗ) refer to refractiveindex.info for some useful background information. The ITO dielectric thickness is optimized to maximize the average reflectivity (R), and generally lines in the range of approximately 25 nm to 75 nm. The reflectivity of Mo/CIGS ODR structures is calculated employing dense and porous ITO dielectric layers.

FIG. 5A shows a graphical diagram of the reflectivity as a function of wavelength for the GaAs semiconductor and aluminum as a metal film. As shown in FIG. 5A, the porous ITO/aluminum ODR structure exhibits reflectivity as a function of wavelength in line 511, with dense ITO/aluminum ODR at line 512 and a bare aluminum reflector at 513. The graphical diagram of FIG. 5A demonstrates the enhanced reflectivity of the ITO/ODR structure by employing the porous ITO to a metal film. As shown in FIG. 5A, the porous ITO/silver ODR structure exhibits reflectivity as a function of wavelength at line 521, with dense ITO/silver ODR at line 522 and a bare silver reflector at 523. The graphical diagram of FIG. 5B demonstrates the enhanced reflectivity of porous ITO deposited on a metal film. FIG. 5C shows the reflectivity as a function of wavelength for porous ITO/gold ODR at line 531, dense ITO/gold ODR at line 532 and a bare gold reflector at line 533, with enhanced reflectivity by employing the porous ITO deposited on the metal film. The graphical diagrams of FIGS. 5A, 5B and 5C exhibit the internal reflectivity versus wavelength for various ITO-containing ODR structures on a substrate, such as GaAs. The ODR structures containing porous ITO have improved internal reflectivity over conventional metal-only films.

Low-n, nanostructured ITO and other similar porous materials can be employed to significantly increase the reflectivity of a metal film on the back side of photovoltaic and optoelectronic devices. For example, as shown in FIG. 6, which is a graphical diagram that compares the calculated reflectivity spectrum of three types of ODR structures (lines 610, 620 and 630) to that of a metal film only (line 640) and uncoated GaAs (line 650). The graphical representation of FIG. 6 includes the reflectivity as a function of wavelength for porous ITO/silver ODR structure at line 610, for porous ITO/gold ODR structure at line 620, for porous ITO/aluminum ODR structure at line 630, for the metal film only structure at line 640 at the uncoated GaAs structure at line 650. These calculations assume internal reflections of photons attempting to pass out the back side of a semiconductor device. As shown, there is significantly increased internal reflectivity of the porous ITO structures as compared to the metal film only and the If the back side of the GaAs-based device is uncoated, Fresnel reflections due to the difference in refractive index between GaAs (n˜3.6) and air (n˜1) will result in reflectivity on the order of approximately 32%. The internal reflectivity can be significantly increased by applying a metal film to the back surface. While metal reflectors are omni-directional, they are limited in their reflectivity performance, typically no more than approximately 90-95% in the best cases. As shown in FIG. 6, some metals have even lower reflectivity, with aluminum on GaAs averaging less than approximately 80% over the wavelength range of interest for solar cells. On the other hand, omni-directional reflector (ODR) structures consisting of a low-n dielectric/metal film bilayer can effectively combine the high peak reflectivity of a distributed Bragg reflector (DBR) with the omni-directionality of metal. As shown in FIG. 6, inserting a porous, nanostructured ITO film (with refractive index n˜1.5) between the GaAs and the aluminum film increases the average reflectivity to over 90%. Even higher reflectivity, in some cases exceeding 98%, can be achieved by combining porous ITO with gold or silver metal films.

The nanostructured dielectric films are typically specular in nature. In a specular film, the dimensions of any inhomogeneous structure are much smaller than the wavelength of visible light. Specular films do not exhibit any measureable scattering, and the reflections are well described by Fresnel equations. However, as the dimensions of the nanostructured material increase, diffuse reflections due to scattering can begin to play a role. Diffuse scattering from a nanostructured dielectric layer in a back-side ODR structure provides an additional mechanism for increasing the optical path length of lower energy photons through the active region of overlying photonic devices.

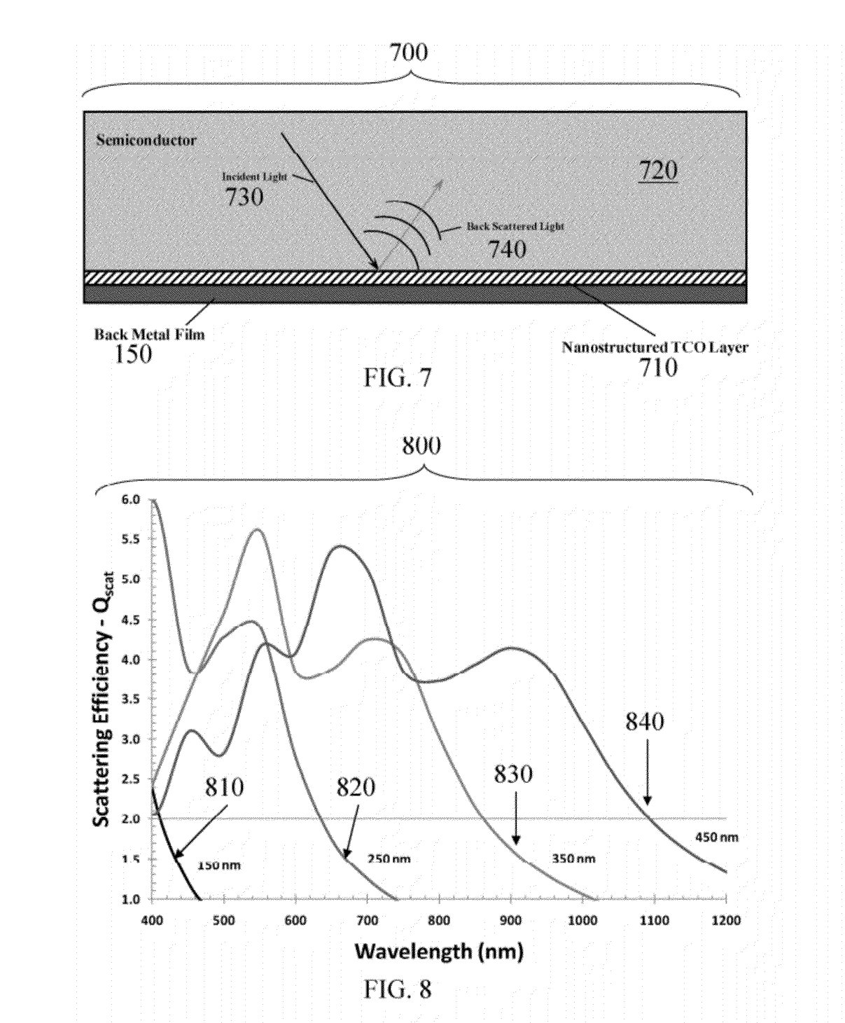

FIG. 7 depicts a schematic cross-sectional diagram of a diffuse ODR structure 700 comprised of a layer of non-specular material 710 (for example TCO) and a metal film 150 on a semiconductor 720. The non-specular nanostructured material 710 (for example TCO) can be synthesized by altering oblique angle deposition conditions. Although the term “TCO” is generally used herein to refer to the layer of nanostructured materials, and describes a transparent conductive oxide, it can include ITO and can be any other non-specular dielectric low-n material commonly known in the art and exhibiting similar characteristics. For example, increasing the sample temperature will enhance surface diffusion, resulting in film with a lower density of larger nanorod structures. As the dimensions of the nanostructures approach the wavelength of visible light, the scattering probability increases.

As shown in FIG. 7, the incident light 730 passes through the semiconductor 720 and is scattered back 740 (internally) to the semiconductor 720. Optical scattering from the non-specular, nanostructured ITO can produce diffuse reflections which enhance the optical path length of back reflected photons, particularly those striking at near normal incidence. The non-specular dielectric layer can consist of any available low-n material. TCO materials such as indium tin oxide and zinc oxide are particularly desirable low-n materials, as they allow the ODR structure to remain electrically conductive.

The absorption and scattering characteristics of small particles are known to depend upon the optical constants of the nanoparticle material, the medium surrounding the nanoparticle, and the wavelength of the incident light. For useful background material on scattering of light, refer to the work of C. F. Bohren and D. R. Huffman, “Absorption and Scattering of Light by Small Particles,” John Wiley & Sons, 1983. Mie scattering theory, for example, can be used to calculate the scattering efficiency (Q_{scat}) of a nanoparticle, and is defined as the ratio of the scattering cross-section and the geometric area. While Mie theory makes the simplifying assumption that the particle is a perfect sphere in shape, Mie scattering calculations can provide a reasonable guide for estimating the impact of particle size on Q_{scat}.

FIG. 8 is a graphical diagram 800 showing the expected variation 810, 820, 830 and 840 in Q_{scat} for ITO nanoparticles having diameters of approximately 150 nm, 250 nm, 350 nm and 450 nm, respectively. For small ITO nanoparticles (below approximately 150 nm), as previously commonly used in the art, the scattering efficiency is very low, resulting in specular films. However, as the ITO nanoparticle size is increased to approximately 350 nm through 450 nm, scattering efficiencies exceeding 2.0 can be obtained over a wide range of wavelengths extending into the infrared. Increasing the sample temperature forms a lower density of larger ITO nanostructures, approaching 350 nm to 450 nm in diameter.

ITO coatings fabricated by oblique-angle deposition are useful in applications which desire an optically transparent and electrically conductive layer with a controllable refractive index. As the deposition angle increases, the porosity of the ITO increases and the refractive index decreases. Low-n, nanostructured ITO layers can be combined with metal films to form high performance, conductive ODR structures. By increasing the dimensions of the nanostructured dielectric film, diffuse ODRs can enhance the optical path of back scattered photons in the semiconductor material.

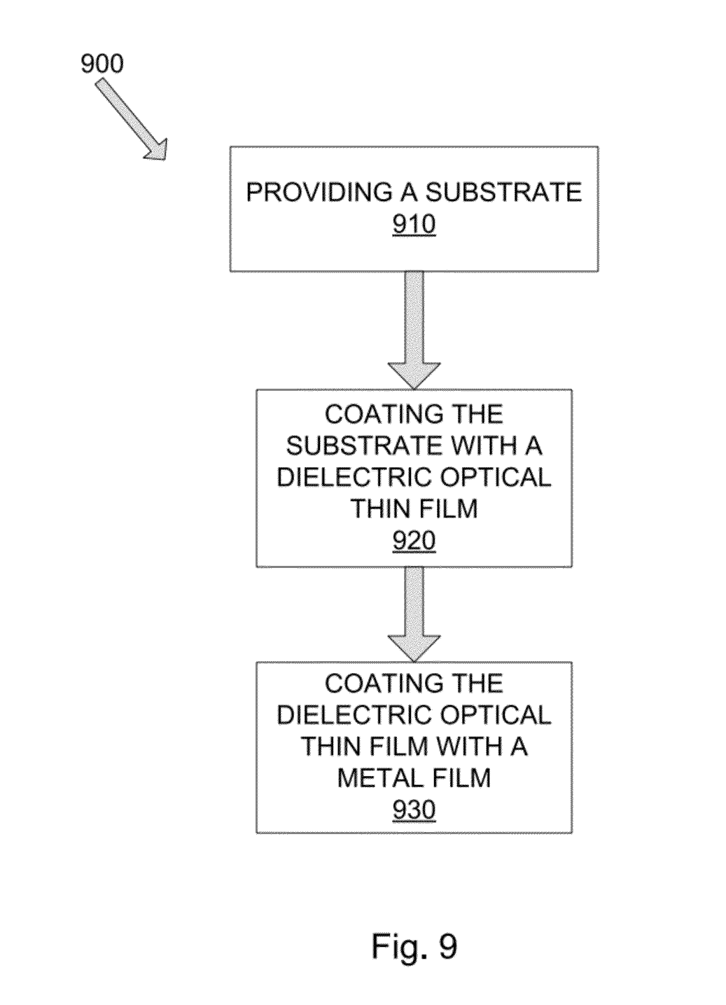

Reference is now made to FIG. 9 showing a flow chart of a procedure 900 for fabricating an ODR structure according to an illustrative embodiment. As shown, at step 910, a substrate is provided. The substrate can comprise a semiconductor device, a photonic device, a photovoltaic solar cell, photodetector sensors and LEDs. At step 920, the substrate is then over-coated with a dielectric optical thin film. The thin-film layer deposited or otherwise coated on the substrate at step 920 comprises a nanostructured material that impacts the characteristics of light waves incident to the substrate. The characteristics of the light waves depend upon the optical properties of the nanostructured material. The nanostructured material can include a plurality of nanoparticles or nanorods, or other nanostructure material known to those ordinarily skilled in the art. The characteristics of light waves that are impacted by the nanostructured material can include, for example, scattering, absorption, reflection and refraction of the light waves. The optical properties of the nanostructure material can include, for example, the size, shape, density and permittivity of the nanostructured material. Finally, at step 930, the optical thin film is over-coated with a metal film. This overall ODR structure comprises the thin-film layer and the metal layer.

Various features and advantages of the illustrative embodiments described hereinabove should now be apparent. The teachings are also readily applicable within ordinary skill to a variety of substrates and/or photovoltaic devices. Although the illustrative embodiments are generally shown and described according to a back reflector structure for a semiconductor device, those having ordinary skill in the art can readily apply the teachings to a wide range of devices, including, for example, both photovoltaic cells and photodetector sensors, as well as LEDs.

The foregoing has been a detailed description of illustrative embodiments of the invention. Various modifications and additions can be made without departing from the spirit and scope of this invention. Each of the various embodiments described above may be combined with other described embodiments in order to provide multiple features. Furthermore, while the foregoing describes a number of separate embodiments of the apparatus and method of the present invention, what has been described herein is merely illustrative of the application of the principles of the present invention. For example, the illustrative embodiments can include additional layers to perform further functions or enhance existing, described functions. Likewise, while not shown, the electrical connectivity of the cell structure with other cells in an array and/or an external conduit is expressly contemplated and highly variable within ordinary skill. More generally, while some ranges of layer thickness and illustrative materials are described herein. It is expressly contemplated that additional layers, layers having differing thicknesses and/or material choices can be provided to achieve the functional advantages described herein. In addition, directional and locational terms such as “top”, “bottom”, “center”, “front”, “back”, “above”, and “below” should be taken as relative conventions only, and not as absolute. Furthermore, it is expressly contemplated that various semiconductor and thin films fabrication techniques can be employed to form the structures described herein. Accordingly, this description is meant to be taken only by way of example, and not to otherwise limit the scope of this invention.

What is claimed is:

1. An omni-directional reflector (ODR) structure for a semiconductor device, the ODR structure comprising:
a non-specular layer of dielectric material that is coated over the semiconductor device; and
a metal film coated over the non-specular layer of dielectric material.

2. The ODR structure of claim 1 wherein the dielectric material is synthesized using at least one of: sputtering, evaporation and oblique angle deposition, to coat the semiconductor device.

3. The ODR structure of claim 1 wherein the dielectric material comprises a nanostructured material including a plurality of nanoparticles or nanorods.

4. The ODR structure of claim 1 wherein the metal film is deposited using at least one of sputtering and evaporation.

5. The ODR structure of claim 1 wherein the metal film comprises at least one of: aluminum, gold and silver.

6. The ODR structure of claim 1 wherein the dielectric material impacts characteristics of light waves incident to the semiconductor, and the characteristics of light waves that are impacted include at least one of: scattering, absorption, reflection and refraction.

7. The ODR structure of claim 6 wherein the characteristics of the light waves depend on optical properties of the dielectric material the optical properties including at least one of: size, shape, density and permittivity of the dielectric material.

8. A method of manufacturing an omni-directional reflector (ODR) structure, the method comprising the steps of:
providing a semiconductor device;
coating the semiconductor device with a dielectric optical thin film;
coating the dielectric optical thin film with a metal film.

9. An omni-directional reflector (ODR) structure comprising:
a thin-film layer deposited on a substrate, the thin-film layer comprising nanostructured material that impacts characteristics of light waves incident to the substrate;
wherein the characteristics of the light waves depend upon optical properties of the nanostructured material.

10. The ODR structure of claim 9 wherein the substrate comprises at least one of a photonic device, a solar cell and a photodetector sensor.

11. The ODR structure of claim 9 wherein the nanomaterial comprises at least one of a plurality of nanoparticles and a plurality of nanorods.

12. The ODR structure of claim 9 wherein the characteristics of light waves include at least one of: scattering, absorption, reflection and refraction.

13. The ODR structure of claim 9 wherein the optical properties of the nanostructured material include at least one of: size, shape, density and permittivity of the nanostructured material.
